(19) United States
(12) Patent Application Publication
(10) Pub. No.: US 2003/0030101 A1
(43) Pub. Date: Feb. 13, 2003

(54) Semiconductor device and manufacturing method thereof

(75) Inventor: Katsuhiko Tamura, Tokyo (JP)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: MITSUBISHI DENKI KABUSHIKI KAISHA, TOKYO (JP)

(21) Appl. No.: 10/113,293

(22) Filed: Apr. 2, 2002

(30) Foreign Application Priority Data
Aug. 8, 2001 (JP) P2001-240472

(51) Int. Cl. H01L 29/788

(52) U.S. Cl. 257/317; 257/318

(57) ABSTRACT

The generation of leakage currents between gate electrodes can be minimized while maintaining the dimensional accuracy and height of the gate electrodes. For example by lamp heating, an oxide film (7) is formed on gate electrodes (4) having a nitride film (8) on their upper surfaces. Thus, even if silicon dust particles are redeposited in between the gate electrodes 4 in a subsequent cleaning process, the generation of leakage currents between the electrodes can be minimized in semiconductor devices. The oxide film (7) is formed only on the side surfaces of the gate electrodes (4), which prevents a decrease in the film thickness in the upper surfaces of the gate electrodes (4) during the process of forming the oxide film (7). Further, there is no need to thicken a gate electrode material film (3) beforehand in order to maintain the height of the gate electrodes (4), which minimizes degradation in dimensional accuracy of the gate electrodes (4).

### BACKGROUND OF THE INVENTION

1. Field of the Invention

The present invention relates to a method of manufacturing a semiconductor device having insulated gate electrodes or wires, and especially to a technique for minimizing leakage currents between the gate electrodes or wires.

2. Description of the Background Art

Due to the high integration of semiconductor devices in recent years, gate electrodes or wires, such as DRAMs, are becoming denser and the spacing therebetween is becoming smaller. Especially for semiconductor devices with such small spacing between the gate electrodes or wires, it is important to ensure dielectric voltage between the gate electrodes or wires and to minimize the generation of leakage currents. For convenience's sake, the following description is primarily given on the gate electrodes.

FIGS. 3A to 3E illustrate the process steps of a conventional semiconductor device manufacturing method. Referring to these drawings, the conventional semiconductor device manufacturing method will now be set forth. Initially, as shown in FIG. 3A, a gate insulating film 2 is formed on a silicon substrate 1. On the gate insulating film 2, as shown in FIG. 3B, a gate electrode material film 3 such as polysilicon and WSi₂ is formed. The gate electrode material film 3 is patterned by photolithography and etching processes as shown in FIG. 3C to form gate electrodes 4. Then, N⁻ diffusion layers 5 are formed in the silicon substrate 1 between the gate electrodes 4 by an impurity implant process as shown in FIG. 3D, and through a cleaning process, sidewalls 6 are formed as shown in FIG. 3E.

As above described, the conventional semiconductor device manufacturing method has the impurity implant and various cleaning processes between the formation of the gate electrodes 4 and the formation of the sidewalls 6. The cleaning process is for removing dust particles on the substrate; however, if dust particles are about equal in size or smaller than the spacing between each electrode, they might go in between the electrodes. Removing such dust particles in between the electrodes is difficult in the cleaning process. More specifically, for example where the spacing between each electrode is 0.3 μm , the removal of dust particles smaller than about 0.3 μm in diameter is difficult. If anything, the cleaning process itself can increase the number of such microscopic dust particles.

Further, many of such dust particles are of silicon, which, when going in between the electrodes, can cause the generation of leakage currents therebetween.

To solve such problems, there have been provided semiconductor devices and manufacturing methods thereof that are capable of maintaining dielectric voltage and preventing the generation of leakage currents even if dust particles go in between the gate electrodes. FIGS. 4A to 4F illustrate the process steps of a conventional semiconductor device manufacturing method capable of preventing the generation of leakage currents by dust particles. First, through the same process steps as shown in FIGS. 3A to 3C, the gate electrodes 4 are formed on the gate insulating film 2, as shown in FIG. 4C, by patterning of the gate electrode material film 3.

At this point in time, for example by thermal oxidation or lamp heating, oxide films 7 are formed on the surfaces of the gate electrodes 4 as shown in FIG. 4D. Then, the N⁻ diffusion layers 5 are formed in the silicon substrate 1 between the gate electrodes 4 by the impurity implant process as shown in FIG. 4E, and through the cleaning process, the sidewalls 6 are formed as shown in FIG. 4F.

By in this way forming the oxide films 7 on the surfaces of the gate electrodes 4 immediately after the gate electrode formation, even if silicon dust particles which could not be removed in the subsequent cleaning process are redeposited in between the gate electrodes 4, the isolation between the silicon dust particles and the gate electrodes 4 is ensured by the oxide films 7. This minimizes, in manufactured semiconductor devices, the generation of leakage currents between the electrodes due to silicon dust particles.

The process step of forming the oxide films 7 on the surfaces of the gate electrodes 4 is performed immediately after the gate electrode formation, i.e., before the cleaning process, but it may be performed after redeposition of silicon dust particles that could not be removed in the cleaning process. Even in this case, the same effect of minimizing leakage currents between the electrodes can be obtained. FIGS. 5A to 5F illustrate the process steps of another conventional semiconductor device manufacturing method capable of preventing the generation of leakage currents by dust particles. First, through the same process steps as shown in FIGS. 3A to 3C, the gate electrodes 4 are formed on the gate insulating film 2 as shown in FIG. 5C by patterning of the gate electrode material film 3. Further, as shown in FIG. 5D, the N⁻ diffusion layers 5 are formed in the silicon substrate 1 between the gate electrodes 4 by the impurity implant process, and then the cleaning process is performed. After that, for example by thermal oxidation or lamp heating, the oxide films 7 are formed on the surfaces of the gate electrodes 4 as shown in FIG. 5E. Then, the sidewalls 6 are formed as shown in FIG. 5F.

In the above manufacturing method, it is possible that redeposited silicon dust particles, which could not be removed in the cleaning process performed before the process step of forming the oxide films 7 on the surfaces of the gate electrodes 4, may exist in between the electrodes. However, such remaining silicon dust particles in between the electrodes are oxidized in the subsequent process step of forming the oxide films 7. This minimizes, in manufactured semiconductor devices, the generation of leakage currents between the electrodes due to silicon dust particles.

As has been described above, the conventional semiconductor device manufacturing methods shown in FIGS. 4A to 4F and 5A to 5F are capable of minimizing leakage currents caused by silicon dust particles which could not be removed in the cleaning process. In these methods, however, not only the side surfaces but also the upper surfaces of the gate electrodes 4 are oxidized to form the oxide films 7. That is, the size of the gate electrodes 4 in finished semiconductor devices becomes smaller than the design value. As a measure against this, it is contemplated to form rather large gate electrodes 4 beforehand. However, increasing the thickness of the gate electrode material film 3 to increase the height of the gate electrodes 4 to be formed makes high-precision machining difficult in the patterning process, resulting in deterioration in dimensional accuracy of the gate electrodes 4. This is a big problem in increasing the packing density of gate electrodes for higher integration of semiconductor devices. Further, maintaining the dimensional accuracy of the gate electrodes 4 involves substantial changes in the process step of forming the gate electrodes 4 from the conventional semiconductor device manufacturing process.

While the foregoing description was primarily given on the gate electrodes, the above conventional techniques are also applied to wires connected to the electrodes; therefore, the same problems also arise in those wires.

### SUMMARY OF THE INVENTION

A first aspect of the present invention is directed to a semiconductor device manufacturing method comprising the steps of: (a) forming a material film for gate electrodes or wires on a semiconductor substrate; (b) forming a nitride film on the material film for the gate electrodes or wires; (c) patterning the nitride film and the material film for the gate electrodes or wires to form the gate electrodes or wires having the nitride film on their upper surfaces; (d) forming an oxide film on side surfaces of the gate electrodes or wires by heating the gate electrodes or wires with the nitride film on their upper surfaces; and (e) cleaning the semiconductor substrate. In this method, even if dust particles which could not be removed in the step (e) are redeposited in between the gate electrodes or wires, the isolation between the dust particles and the gate electrodes or wires can be ensured. This minimizes, in manufactured semiconductor devices, the generation of leakage currents between the gate electrodes or wires due to dust particles.

Further, in the step (d), the oxide film is not formed on the upper surfaces of the gate electrodes or wires, which minimizes a decrease in the film thickness in the upper surfaces of the gate electrodes or wires. Therefore, the height of the gate electrodes or wires can be maintained without increasing the thickness of the material film for the gate electrodes or wires in the step (a).

Furthermore, since in the step (b), the nitride film to be formed on the gate electrodes or wires may be small in thickness, degradation in dimensional accuracy in forming the gate electrodes or wires by patterning in the step (c) can be minimized.

This avoids the necessity for considerably changing the step of forming the gate electrodes or wires from the conventional semiconductor device manufacturing process, in order to maintain the dimensional accuracy of the gate electrodes or wires.

According to a second aspect of the present invention, in the semiconductor device manufacturing method of the first aspect, the step (d) is performed before the step (e). Thus, even if dust particles which could not be removed in the step (e) are redeposited in between the gate electrodes or wires, the isolation between the dust particles and the gate electrodes or wires can be ensured by the oxide film formed in the step (d). This minimizes, in manufactured semiconductor devices, the generation of leakage currents between the gate electrodes or wires due to dust particles.

According to a third aspect of the present invention, in the semiconductor device manufacturing method of the first aspect, the step (d) is performed after the step (e). Thus, even if dust particles which could not be removed in the step (e) are redeposited in between the gate electrodes or wires, the dust particles are oxidized in the subsequent step (d). This minimizes, in manufactured semiconductor devices, the generation of leakage currents between the gate electrodes or wires due to dust particles.

A fourth aspect of the present invention is directed to a semiconductor device comprising: either gate electrodes or wires having a nitride film on their upper surfaces and an oxide film on their side surfaces. This minimizes the generation of leakage currents between the gate electrodes or wires due to dust particles.

Further, the presence of the nitride film on the upper surfaces of the gate electrodes or wires prevents the oxide film to be formed on the upper surfaces of the gate electrodes or wires during the process of forming the oxide film on the side surfaces of the gate electrodes or wires; therefore, the height of the gate electrodes or wires can be maintained. This avoids the necessity for increasing the height of the gate electrodes or wires to be formed beforehand and thus does not cause a problem of degradation in dimensional accuracy in forming the gate electrodes or wires.

Therefore, an object of the prevent invention is to solve the conventional problems previously described and to provide a semiconductor device manufacturing method capable of maintaining the dimensional accuracy and height of the gate electrodes or wires and preventing the generation of leakage currents between the gate electrodes or wires.

These and other objects, features, aspects and advantages of the present invention will become more apparent from the following detailed description of the present invention when taken in conjunction with the accompanying drawings.

### BRIEF DESCRIPTION OF THE DRAWINGS

FIGS. 1A to 1G illustrate the process steps of a semiconductor device manufacturing method according to a first preferred embodiment;

FIGS. 2A to 2G illustrate the process steps of a semiconductor device manufacturing method according to a second preferred embodiment;

FIGS. 3A to 3E illustrate the process steps of a conventional semiconductor device manufacturing method;

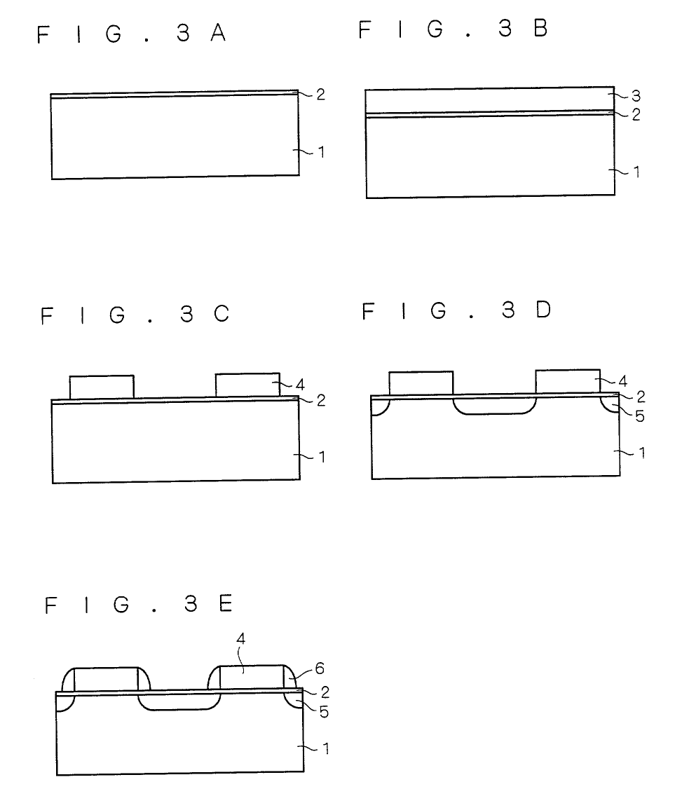

FIGS. 4A to 4F illustrate the process steps of a conventional semiconductor device manufacturing method capable of preventing the generation of leakage currents by dust particles; and

FIGS. 5A to 5F illustrate the process steps of another conventional semiconductor device manufacturing method capable of preventing the generation of leakage currents by dust particles.

### DESCRIPTION OF THE PREFERRED EMBODIMENTS

<First Preferred Embodiment>

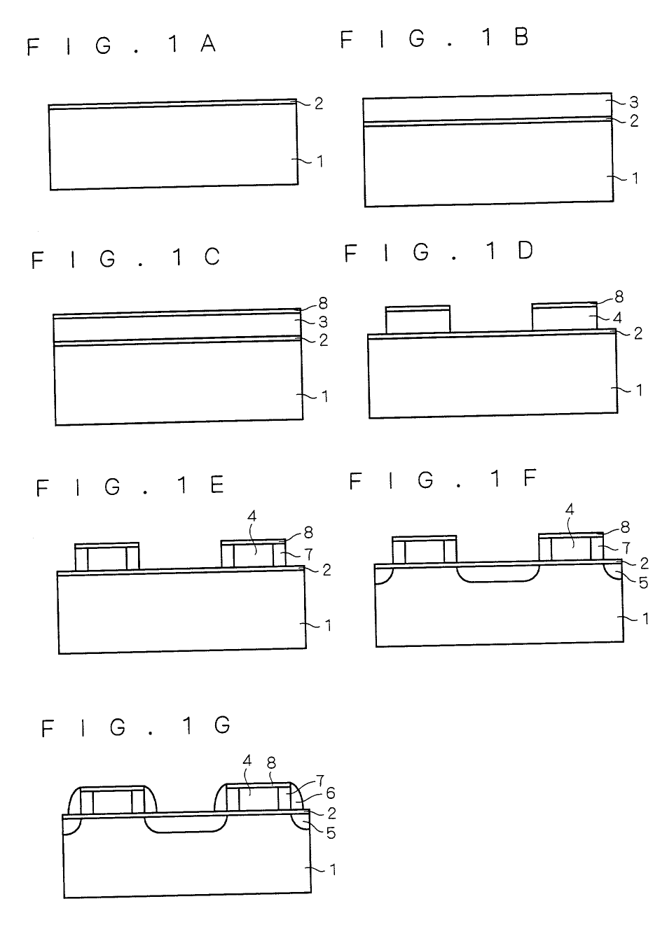

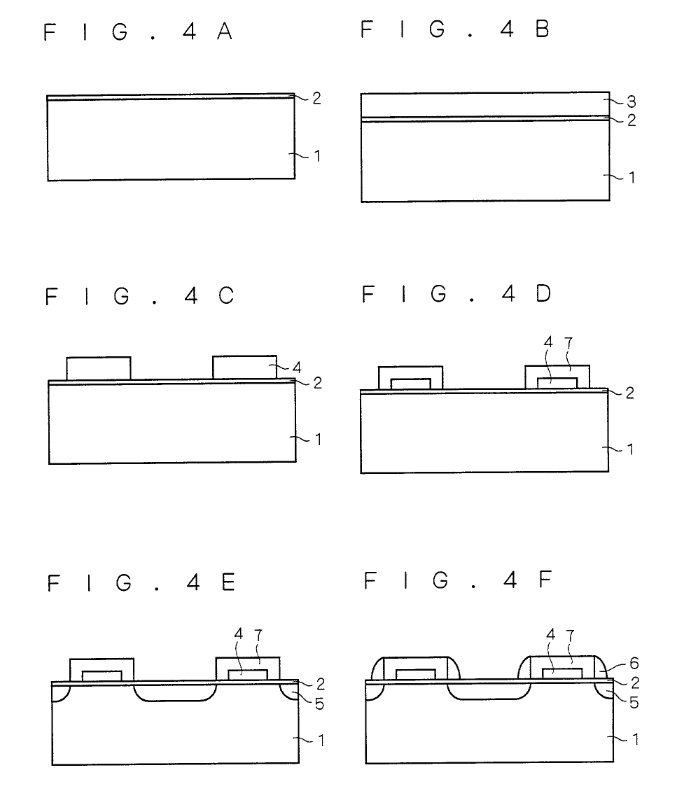

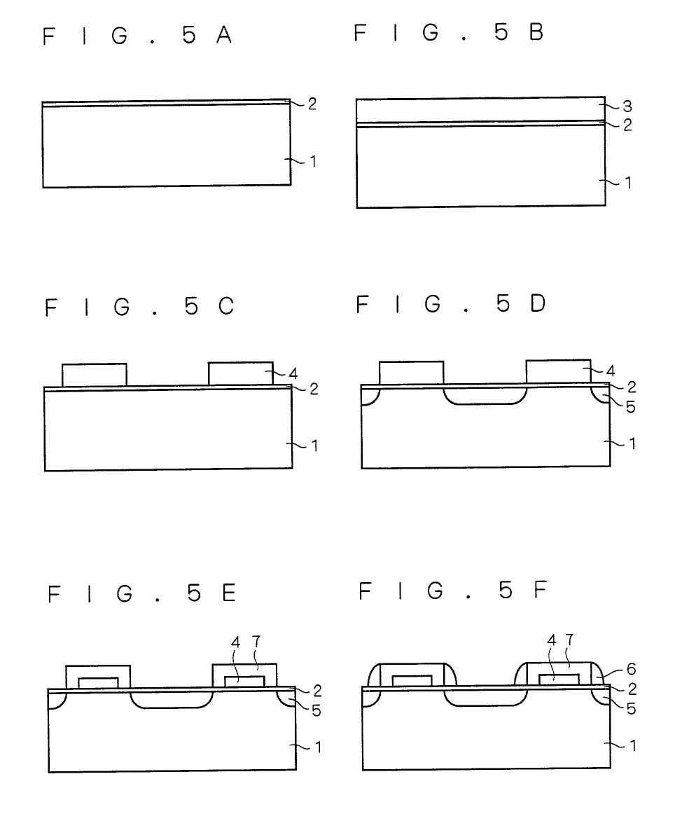

FIGS. 1A to 1G illustrate the process steps of a semiconductor device manufacturing method according to a first preferred embodiment. Referring to these drawings, the semiconductor device manufacturing method of the first preferred embodiment will now be set forth. In the drawings, components identical with those of FIGS. 4A to 4F and 5A to 5F are denoted by the same reference numerals. Initially, as shown in FIG. 1A, a gate insulating film 2 is formed on a silicon substrate 1. Then, a gate electrode material film 3 such as polysilicon and WSi₂ is formed on the gate insulating film 2 as shown in FIG. 1B, and a nitride film 8 is formed on the gate electrode material film 3 as shown in FIG. 1C. The gate electrode material film 3 and the nitride film 8 are then patterned by photolithography and etching processes as shown in FIG. 1D, thereby to form gate electrodes 4 having the nitride film 8 on their upper surfaces.

At this point in time, for example by thermal oxidation or lamp heating, oxide films 7 are formed on the surfaces of the gate electrodes 4 as shown in FIG. 1E. At this time, since the upper surfaces of the gate electrodes 4 are covered with the nitride film 8, the oxide films 7 are formed only on the side surfaces of the gate electrodes 4.

Then, N⁻ diffusion layers 5 are formed in the silicon substrate 1 between the gate electrodes 4 by an impurity implant process as shown in FIG. 1F, and through a cleaning process, sidewalls 6 are formed as shown in FIG. 1G.

In the above manufacturing method, by forming the oxide films 7 on the side surfaces of the gate electrodes 4 immediately after the gate electrode formation, even if silicon dust particles which could not be removed in the subsequent cleaning process are redeposited in between the gate electrodes 4, the insulation between the silicon dust particles and the gate electrodes 4 is ensured by the oxide films 7, as in the conventional method shown in FIGS. 4A to 4F. This minimizes, in manufactured semiconductor devices, the generation of leakage currents between the electrodes due to silicon dust particles.

Further, the oxide films 7 are formed only on the side surfaces of the gate electrodes 4, not on the upper surfaces. This minimizes a decrease in the film thickness in the upper surfaces of the gate electrodes 4. It is thus not necessary to thicken the gate electrode material film 3 to be formed in order to ensure the height of the gate electrodes 4. In addition, the nitride film 8 to be formed on the gate electrode material film 3 may be smaller in thickness than the oxide films 7. Thus, degradation in dimensional accuracy in forming the gate electrodes 4 by the subsequent patterning can further be minimized than in the case of thickening the gate electrode material film 3 to be formed beforehand in order to maintain the height of the gate electrodes 4. This avoids the necessity for considerably changing the process step of forming the gate electrodes 4 from the conventional semiconductor device manufacturing process, in order to maintain the dimensional accuracy of the gate electrodes 4.

From the above, the semiconductor device manufacturing method according to this preferred embodiment is capable of maintaining the dimensional accuracy and height of the gate electrodes 4 and minimizing leakage currents between the electrodes in manufactured semiconductor devices. This is especially effective for increasing the packing density of electrodes in devices, such as DRAMs, that provide small spacing between the electrodes, thereby contributing to higher integration of semiconductor devices.

In the present example, the gate electrodes are taken as examples for application of the present invention. It is, however, apparent that the present invention is also applicable to wires connected to those electrodes and thus can achieve the effect of preventing the generation of leakage currents between the wires.

<Second Preferred Embodiment>

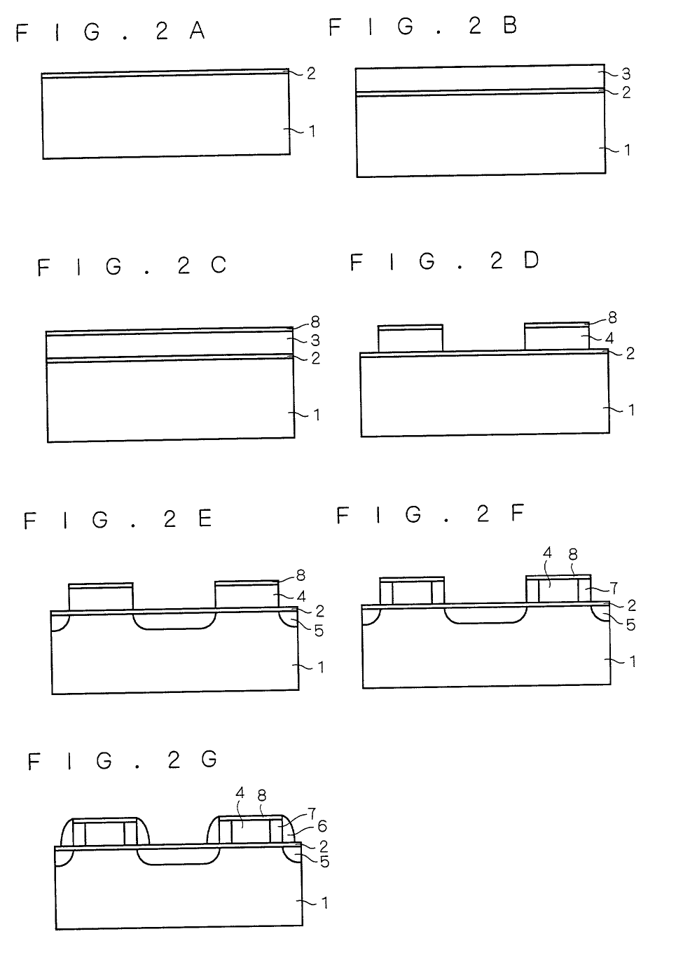

FIGS. 2A to 2G illustrate the process steps of a semiconductor device manufacturing method according to a second preferred embodiment. Referring to these drawings, the semiconductor device manufacturing method of the second preferred embodiment will now be set forth. In the drawings, components identical with those of FIGS. 1A to 1G are denoted by the same reference numerals.

First, through the same process steps as shown in FIGS. 1A to 1D, the gate electrode material film 3 and the nitride film 8 formed on the gate insulating film 2 are patterned to form the gate electrodes 4 having the nitride films 8 on their upper surfaces as shown in FIG. 2D. Further, the N⁻ diffusion layers 5 are formed in the silicon substrate 1 between the gate electrodes 4 by the impurity implant process as shown in FIG. 2E, and then the cleaning process is performed.

After that, for example by thermal oxidation or lamp heating, the oxide films 7 are formed on the surfaces of the gate electrodes 4 as shown in FIG. 2F. At this time, since the upper surfaces of the gate electrodes 4 are covered with the nitride film 8, the oxide films 7 are formed only on the side surfaces of the gate electrodes 4.

Then, the sidewalls 6 are formed as shown in FIG. 2G.

In the above manufacturing method, it is possible that redeposited silicon dust particles, which could not be removed in the cleaning process performed before the process step of forming the oxide films 7 on the surfaces of the gate electrodes 4, may exist in between the electrodes. However, as in the conventional method shown in FIG. 5, such remaining silicon dust particles in between the electrodes are oxidized in the subsequent process step of forming the oxide films 7. This minimizes, in manufactured semiconductor devices, the generation of leakage currents between the electrodes due to silicon dust particles.

Further as in the first preferred embodiment, the oxide films 7 are formed only on the side surfaces of the gate electrodes 4, not on the upper surfaces. This minimizes a decrease in the film thickness in the upper surfaces of the gate electrodes 4. It is thus not necessary to thicken the gate electrode material film 3 to be formed in order to ensure the height of the gate electrodes 4. In addition, the nitride film 8 to be formed on the gate electrode material film 3 may be smaller in thickness than the oxide films 7. Thus, degradation in dimensional accuracy in forming the gate electrodes 4 by the subsequent patterning can further be minimized than in the case of thickening the gate electrode material film 3 to be formed beforehand in order to maintain the height of the gate electrodes 4. This avoids the necessity for considerably changing the process step of forming the gate electrodes 4 from the conventional semiconductor device manufacturing process, in order to maintain the dimensional accuracy of the gate electrodes 4.

From the above, the semiconductor device manufacturing method according to this preferred embodiment is capable of maintaining the dimensional accuracy and height of the gate electrodes 4 and preventing the generation of leakage currents between the gate electrodes in manufactured semiconductor devices. This is especially effective for increasing the packing density of electrodes in devices, such as DRAMs, that provide small spacing between the electrodes, thereby contributing to higher integration of semiconductor devices.

In the present example, the gate electrodes are taken as examples for application of the present invention. It is, however, apparent that the present invention is also applicable to wires connected to those electrodes and thus can achieve the effect of preventing the generation of leakage currents between the wires.

While the invention has been shown and described in detail, the foregoing description is in all aspects illustrative and not restrictive. It is therefore understood that numerous modifications and variations can be devised without departing from the scope of the invention.

What is claimed is:

1. A semiconductor device manufacturing method comprising the steps of:
(a) forming a material film for gate electrodes or wires on a semiconductor substrate;
(b) forming a nitride film on said material film for said gate electrodes or wires;
(c) patterning said nitride film and said material film for said gate electrodes or wires to form said gate electrodes or wires having said nitride film on their upper surfaces;
(d) forming an oxide film on side surfaces of said gate electrodes or wires by heating said gate electrodes or wires with said nitride film on their upper surfaces; and
(e) cleaning said semiconductor substrate.

2. The semiconductor device manufacturing method according to claim 1, wherein
said step (d) is performed before said step (e).

3. The semiconductor device manufacturing method according to claim 1, wherein
said step (d) is performed after said step (e).

4. A semiconductor device comprising:
either gate electrodes or wires having a nitride film on their upper surfaces and an oxide film on their side surfaces.
